(19) United States
(12) Patent Application Publication
(10) Pub. No.: US 2015/0382517 A1
(43) Pub. Date: Dec. 31, 2015

(54) RF AND EMF METER SHIELD

(71) Applicant: Vincent A LaPrise, Macomb, MI (US)

(72) Inventor: Vincent A LaPrise, Macomb, MI (US)

(21) Appl. No.: 14/755,271

(22) Filed: Jun. 30, 2015

Related U.S. Application Data
(60) Provisional application No. 62/018,851, filed on Jun. 30, 2014.

(51) Int. Cl. H05K 9/00

(52) U.S. Cl. CPC H05K 9/0043

(57) ABSTRACT

A flexible barrier or shield protecting consumers from RF and/or EMF Radiation emitted by electronic wireless devices such as “Smart Meters” is disclosed. The invention is configured to enclose un-shielded portions of electronic wireless devices such as “Smart Meters” to protect consumers from stray radiation that could potentially hurt them physically. The invention includes at least one metallic material creating a natural barrier providing attenuation properties aiding in the reduction of the emission of Radio Frequency Radiation and Electro Mechanical Frequency Radiation, and preferably an elastic type material for adjusting the size of the barrier shield to allow it to be secured firmly on electronic, electromechanical and wireless devices. The invention does not require tools or physical alterations to install on a variety of device sizes for easy universal installation, and is comparatively lighter in weight inexpensive to manufacture and ship.

### CROSS-REFERENCE TO RELATED APPLICATIONS

This application claims the benefit of priority of Provisional Patent Application No. 62/018,851, filed 30 Jun. 2014.
Title of Invention: RF AND EMF METER SHIELD

### STATEMENT REGARDING FEDERALLY SPONSORED

Not Applicable

### RESEARCH OR DEVELOPMENT

Not Applicable

### THE NAMES OF THE PARTIES TO A JOINT RESEARCH AGREEMENT

Not Applicable

### INCORPORATION-BY-REFERENCE OF MATERIAL SUBMITTED, INCLUDING ON A COMPACT DISC

Not Applicable

### BACKGROUND OF THE INVENTION

1. Field of the Invention

The present invention relates to a universal flexible barrier shield to reduce potentially harmful radio frequency (RF) and electromagnetic frequency (EMF) radiation for safety of consumers and more specifically to related articles, methods of manufacturing same, and methods of using same.

2. Description of the Prior Art

Conventional smart meter RF/EMF shields are well known in the art, including one of the most common types of rigid shields that include heavy metallic smart meter covers for press fitting over a conventional round glass meter.

However, practitioners of those inventions have become aware of certain problems, which are presented by those prior art inventions. One particular problem that has plagued users has been that the rigid shield doesn't fit properly and RF/EMF radiation leaks around the outside of the shield. Furthermore, there are complexities, which give rise to ineffective shielding, difficulty installing, and high cost in manufacturing and shipping. Practitioners of other inventions consist primarily of cushioned rigid materials designed to protect the electrical devices they enclose from damage and are not designed for attenuating the emission of Radio Frequency Radiation and Electro Mechanical Frequency Radiation. Yet practitioners of other inventions consist primarily of barriers to shield only portions of a person from Radio Frequency; such as covering portions of a patient while an MRI or x-ray is being performed. However, these inventions do not enclose the emitting electronic devices to aid in the protection of all living matter in the vicinity of the emitting electrical device from the effects of Radio Frequency Radiation and Electro Mechanical Frequency Radiation.

As such, even with their inadequacies, there are known barriers for RF and EMF. The majority of these barriers are made from solid, heavy, non-flexible materials and must be custom formed to fit each unique application. Existing common uses are related to barriers for components on circuit boards, barriers for mobile devices, and barriers for protection from MRI scans. In essence, a Faraday cage is built, albeit a rigid cage made of metal.

In recent years, as technology has continued to advance, many new forms of RF and EMF Radiation are emitted from an increasing number of devices. These recently introduced devices include such devices as “Smart Meters” used by utility companies for monitoring consumer's utility use. More specifically RF and EMF Radiation emitted from the “Smart Meters” used for monitoring consumer electrical use, monitoring consumer gas use and monitoring consumer water use.

The inventor knows of no currently available barriers or shields that are versatile and flexible enough to be used for protecting consumers from RF Radiation and EMF Radiation emitted from the variety of physical sizes and shapes of “Smart Meters” and electronic devices or that are comparatively lighter in weight simple to install (requiring no tools) and inexpensive to manufacture and ship. The present invention seeks to provide such a versatile and flexible barrier and shield to protect consumers from RF Radiation and EMF Radiation emitted for the majority of the various physical sizes and shapes of “Smart Meters” and electronic devices.

Therefore, it would be desirable to the consumer industry if there was provided a flexible barrier shield that completely covers any size or shape of smart meter to provide a full shield against RF/EMF radiation, and method of making such a light weight, flexible shield, and a method of using and installing the shield.

### SUMMARY OF THE INVENTION

In accordance with the above-noted desires of the industry, the present invention provides various aspects, including a flexible barrier shield device, a method of making same, and a method of using and installing same. The present invention overcomes all, or at least some of the aforementioned problems with the prior art because it includes the use of a novel light weight flexible fabric with metal segments woven there-through fashioned into a flexible barrier shield with an elastic outer ring to accommodate any number of sizes or shapes of smart meter outer dimensions.

The present invention relates to a flexible covering for attenuating the emission of electromagnetic “Smart Meters” used by utility companies for reporting utility use. Opposed to the rigid covers in the prior art, my invention is shaped and sewn to cover all sizes and types of smart meters that emit RF and EMF radiation, thereby shielding all living matter in the vicinity of the emitting electrical device from the effects of Radio Frequency Radiation and Electro Mechanical Frequency Radiation. It is ideally manufactured with materials and in such a way as to be comparatively lighter in weight, inexpensive to manufacture, and inexpensive to ship.

The novel versatile and light weight flexible material of an RF and EMF shielding fabric is to be assembled and sized in such a way to create a “bag” shape in order to enclose or contain various physical sized and shaped electronic devices that may emit RF and/or EMF Radiation. More specifically, the size and shape of this bag invention is designed in such a way to easily adapt to fit and enclose or contain the majority of “Smart Meter” glass cover sizes and shapes. This bag invention is preferably closed on one end and open on the other end. The open end of this bag invention has an elastic type material in order to expand and contract, to securely hold the bag invention onto various physical sized and shaped electrical devices without the use of tools or without physical alterations to the invention.

The material used in manufacturing this bag invention is made from any RF/EMF shielding material or substrate that is versatile and flexible. Preferably the material is a versatile and flexible material that is strong, durable and that endures natures elements, such as sun, rain, snow, sleet, hot temperature and cold temperatures for an extended period of time. Said material or membrane shall be sheeted, rolled, spun-bound, or woven and coated, encrusted, impregnated, layered, intertwined or woven with a mixture of metallic materials proportioned to act as a natural barrier or shield in order to provide attenuation properties aiding in the reduction of the emission of Radio Frequency Radiation and Electro Mechanical Frequency Radiation. Assembly of the invention is bonded together by at least one method including gluing, adhesive, ultrasonic weld, or sewing at the seams and ends.

The invention is particularly useful for applications of smart meters used by utility companies. Although the invention will be described by way of examples hereinbelow for specific aspects having certain features, it must also be realized that minor modifications that do not require undo experimentation on the part of the practitioner are covered within the scope and breadth of this invention. Additional advantages and other novel features of the present invention will be set forth in the description that follows and in particular will be apparent to those skilled in the art upon examination or may be learned within the practice of the invention. Therefore, the invention is capable of many other different aspects and its details are capable of modifications of various aspects, which will be obvious to those of ordinary skill in the art all without departing from the spirit of the present invention. Accordingly, the rest of the description will be regarded as illustrative rather than restrictive.

### BRIEF DESCRIPTION OF THE DRAWINGS

For a further understanding of the nature and advantages of the expected scope and various aspects of the present invention, reference shall be made to the following detailed description, and when taken in conjunction with the accompanying drawings, in which like parts are given the same reference numerals, and wherein;

FIG. 1 is a perspective view of the present invention installed on a typical “Smart Meter” in accordance with the present invention;

FIG. 2 is a perspective view of the present invention, configured “in-side-out” as it would be manufactured; and

FIG. 3 is a environmental perspective view of the present invention installed on a typical “Smart Meter”.

### REFERENCE NUMERALS IN THE DRAWINGS

11 RF/EMF shield, general denotation

12 elastic edge

13 smart meter enclosure

14 elastic edge

15 main body

16 end panel

17 open end

18 closed end

19 bottom seam

20 smart meter enclosure

21 present invention

### DETAILED DESCRIPTION OF THE INVENTION

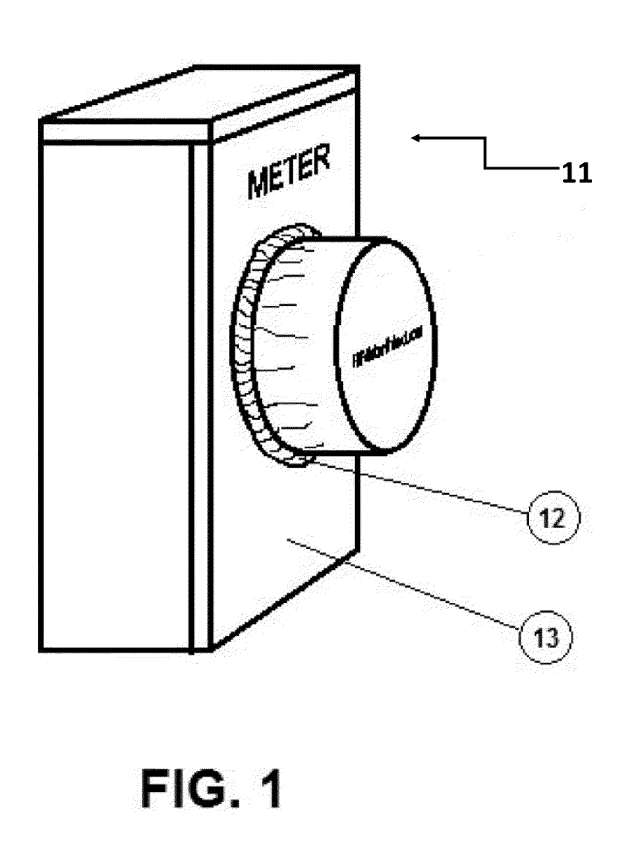

Referring now to the drawings in detail, FIG. 1 is a perspective view of an RF/EMF flexible barrier shield made in accordance with the present invention, generally indicated by the numeral 11, which also includes elastic edge 12. FIG. 1 shows this perspective view of the present invention installed properly over a typical utility “Smart Meter” 13. The open end contains an elastic type material 12 shown rolled up fitting securely over the “Smart Meter” glass cover. The elastic type material 12 snugly holds the invention in place over the “Smart Meter” glass cover. The flexible barrier shield 11 is constructed of a material or substrate that is versatile and flexible. Preferably the material is a versatile and flexible RF/EMF shielding material that is strong, durable and that endures natures elements; such as sun, rain, snow, sleet, hot temperature and cold temperatures; for an extended period of time. This material or membrane is sheeted, rolled, spun-bound, or woven and coated, encrusted, impregnated, layered, intertwined or woven with a mixture of metallic materials proportioned to act as a natural barrier or shield in order to provide attenuation properties aiding in the reduction of the emission of Radio Frequency Radiation and Electro Mechanical Frequency Radiation that protects consumers from electrical devices that may emit RF and/or EMF Radiation.

With proper installation, a seal is created between the invention's metallic materials and the metal enclosure containing the “Smart Meter” 12. Ideally, the invention combined with the “Smart Meter” enclosure creates a complete barrier or shield protecting consumers from RF and/or EMF Radiation.

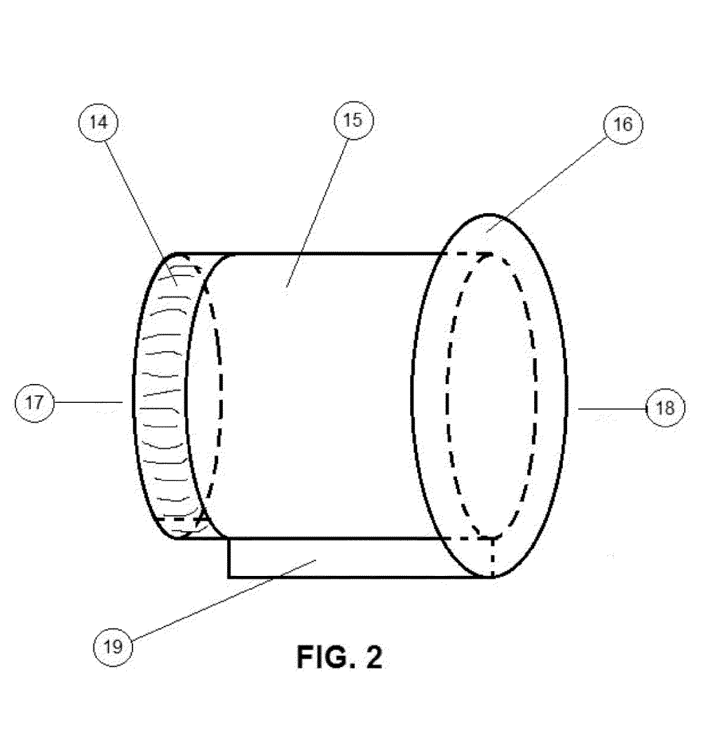

FIG. 2 shows the present invention “inside-out” as it would be manufactured. An elastic type material 14 is held in place by folding over the substrate material at open end 17 and seaming the folded edge to main body 15 using glue, adhesive, ultrasonic weld, or sewing.

Both ends of the main body 15 are seamed together using at least one method of gluing, adhesives, ultrasonic welding, or sewing, thereby creating a bottom seam 19. End panel 16 is seamed to the main body 15 using glue, adhesive, ultrasonic weld, or sewing at closed end 18.

After being assembled the flexible barrier shield is then turned “right-side-out” for use.

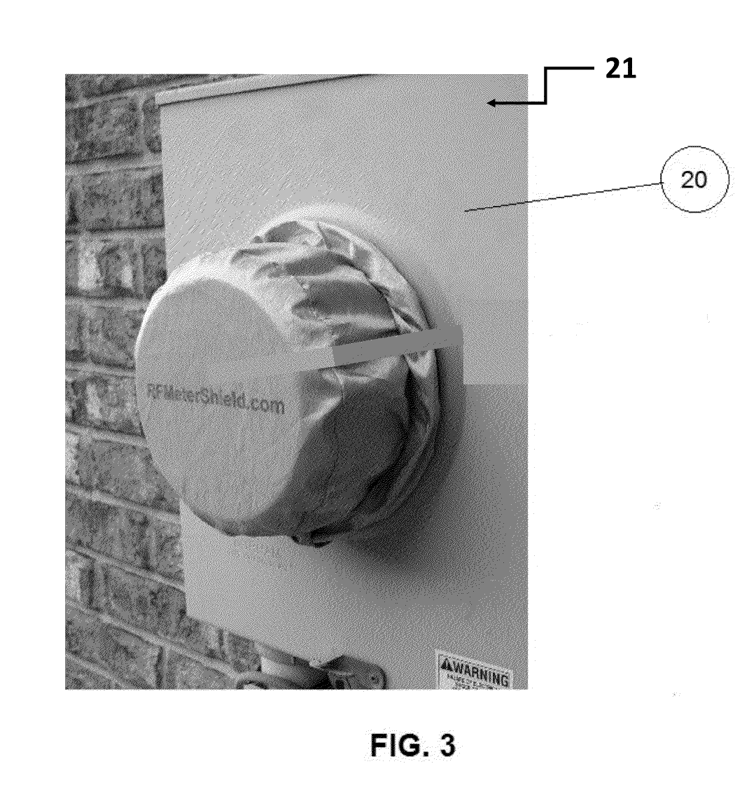

FIG. 3 shows an environmental perspective view of the present invention 21 in use and installed over a typical “Smart Meter” 20 acting as a natural barrier or shield that protects consumers from electrical devices that may emit RF and/or EMF Radiation.

Therefore, a flexible barrier shield for protecting consumers from RF and EMF Radiation emitted by electronic, electromechanical, and electronic wireless devices, including smart meters, is provided. Especially, a barrier that protects consumers from RF or EMF Radiation emitted by such electronic devices is provided that is universally designed to securely fit a variety of device sizes from one pattern. This barrier shield requires no tools or physical alterations to install the device, merely stretching the elastic outer form, securing the barrier shield over the device to be shielded, and insuring that there is no place where the radiation can leak out is the simple and easy method of installing the barrier shield over any number of different sizes and shapes of the electronic, wireless or smart meter device.

In summary, numerous benefits have been described which result from employing any or all of the concepts and the features of the various specific aspects of the present invention, or those that are within the scope of the invention. The barrier shield acts as a universally fitting, radiation reducing, and elementally protecting device and is comparatively easier to install, lighter in weight, and inexpensive to manufacture and ship.

The foregoing description of a preferred aspect of the invention has been presented for purposes of illustration and description. It is not intended to be exhaustive or to limit the invention to the precise form disclosed. Obvious modifications or variations are possible in light of the above teachings with regards to the specific aspects. The aspect was chosen and described in order to best illustrate the principles of the invention and its practical applications to thereby enable one of ordinary skill in the art to best utilize the invention in various aspects and with various modifications as are suited to the particular use contemplated. It is intended that the scope of the invention be defined by the claims which are appended hereto.

What is claimed is:

1. A bather shield for the reduction of RF and EMF radiation, comprising:
a fabric, material, membrane and/or substrate that is versatile and flexible;
material shall be sheeted, rolled, spun-bound, or woven and coated, encrusted, impregnated, layered, intertwined or woven with a mixture of metallic materials proportioned to act as a natural barrier or shield in order to provide attenuation properties aiding in the reduction of the emission of Radio Frequency Radiation and Electro Mechanical Frequency Radiation that reduces RF and EMF radiation emitted by electrical devices;
fabric, material, membrane, and/or substrate is physically sized, shaped, assembled and/or bonded together in such a way to create a flexible “bag” structure in order to enclose various electrical devices; and
an elastic type material is applied to a portion of the structure allowing the structure to expand and contract in order to secure to and around various electrical devices.

2. The bather shield for the reduction of RF and EMF radiation of claim 1, wherein the fabric, material, membrane, or substrate is physically sized, shaped, assembled and/or bonded together in such a way to create a flexible “bag” structure in order to easily adapt to fit and enclose or contain “Smart Meter” devices.

3. The bather shield for the reduction of RF and EMF radiation of claim 1, wherein the fabric, material, membrane, or substrate is physically sized, shaped, assembled and/or bonded together in such a way to create a flexible “bag” structure in order to easily adapt to fit and enclose or contain a range of various sized and shaped electrical devices.

4. The bather shield for the reduction of RF and EMF radiation of claim 2, wherein the fabric, material, membrane, or substrate is physically sized, shaped, assembled and/or bonded together in such a way to create a flexible “bag” structure in order to easily adapt to fit and enclose or contain a range of various sized and shaped “Smart Meter” devices.

5. The bather shield for the reduction of RF and EMF radiation of claim 1, wherein the fabric, material, membrane, or substrate is physically sized, shaped, assembled and/or bonded together in such a way to create a flexible “bag” structure in order to minimize manufacturing costs.

6. The bather shield for the reduction of RF and EMF radiation of claim 2, wherein the fabric, material, membrane, or substrate is physically sized, shaped, assembled and/or bonded together in such a way to create a flexible “bag” structure in order to minimize manufacturing costs.

7. The bather shield for the reduction of RF and EMF radiation of claim 1, wherein the fabric, material, membrane, or substrate is of minimal weight in order to minimize transport costs.

8. The bather shield for the reduction of RF and EMF radiation of claim 2, wherein the fabric, material, membrane, or substrate is of minimal weight in order to minimize transport costs.

9. The bather shield for the reduction of RF and EMF radiation of claim 1, wherein the fabric, material, membrane, or substrate is physically sized, shaped, assembled and/or bonded together in such a way to create a flexible “bag” structure in order to easily adapt to fit and enclose or contain a range of various sized and shaped electrical devices without the use of tools for installation.

10. The bather shield for the reduction of RF and EMF radiation of claim 2, wherein the fabric, material, membrane, or substrate is physically sized, shaped, assembled and/or bonded together in such a way to create a flexible “bag” structure in order to easily adapt to fit and enclose or contain a range of various sized and shaped “Smart Meter” devices without the use of tools for installation.
